(19) United States
(12) Patent Application Publication
(10) Pub. No.: US 2015/0206994 A1
(43) Pub. Date: Jul. 23, 2015

(54) SOLAR CELL FRONT CONTACT WITH THICKNESS GRADIENT

(71) Applicant: TSMC Solar Ltd., Taichung City (TW)

(72) Inventor: Chia-Hung TSAI, Kaohsiung City (TW)

(73) Assignee: TSMC Solar Ltd., Taichung City (TW)

(21) Appl. No.: 14/161,743

(22) Filed: Jan. 23, 2014

(51) Int. Cl. H01L 31/0224; H01L 31/18

(52) U.S. Cl. CPC H01L 31/022433; H01L 31/1884

(57) ABSTRACT

A solar cell has a back contact layer over a substrate. The substrate has a scribe line extending through it. An absorber layer is over the back contact layer. A front contact layer is over the absorber layer. The front contact layer has a first end and a second end opposite the first end. The scribe line is closer to the second end than to the first end. The front contact layer has a thickness above the first end that is greater than the thickness of the front contact layer at the scribe line.

### PRIORITY CLAIM AND CROSS-REFERENCE

None.

### BACKGROUND

This disclosure related to fabrication of thin film photovoltaic cells.

Solar cells are electrical devices for generation of electrical current from sunlight by the photovoltaic (PV) effect. Thin film solar cells have one or more layers of thin films of PV materials deposited on a substrate. The film thickness of the PV materials can be on the order of nanometers or micrometers.

Examples of thin film PV materials used as absorber layers in solar cells include copper indium gallium selenide (CIGS) and cadmium telluride. Absorber layers absorb light for conversion into electrical current. Solar cells also include front and back contact layers to assist in light trapping and photo-current extraction and to provide electrical contacts for the solar cell. The front contact typically comprises a transparent conductive oxide (TCO) layer. The TCO layer transmits light through to the absorber layer and conducts current in the plane of the TCO layer. In some systems, a plurality of solar cells are arranged adjacent to each other, with the front contact of each solar cell conducting current to the next adjacent solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross sectional view of a solar panel, in accordance with some embodiments.

FIG. 2 is a graph showing electroluminosity of the solar panel of FIG. 1, in accordance with some embodiments.

FIG. 3 is a diagram of current density of the solar panel of FIG. 1, in accordance with some embodiments.

FIG. 4 is a cross sectional view of a solar panel having a TCO layer with a linear thickness gradient, in accordance with some embodiments.

FIG. 5 is a cross sectional view of a solar panel having a TCO layer with a non-linear thickness gradient, in accordance with some embodiments.

FIG. 6A shows a step of depositing the TCO layer of FIG. 4 or FIG. 5, in accordance with some embodiments.

FIG. 6B shows deposition of additional TCO layer material on the substrate of FIG. 6A, with an oblique shutter angle.

FIG. 7 shows another embodiment of an apparatus for providing an oblique TCO material stream for making a solar cell, in accordance with some embodiments.

FIG. 8 shows an alternative configuration of a sputtering chamber, having a variable aperture for forming the TCO layer, in accordance with some embodiments.

FIG. 9 is a flow chart of a method of making a solar cell, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure and the accompanying drawings, like reference numerals indicate like items, unless expressly stated to the contrary.

In a thin-film photovoltaic solar cell, it is desirable for the front contact to have high optical transmittance so the absorber can absorb more photons, and also to have high conductivity, to reduce series resistance. Although reducing the dopant concentration provides higher transmittance to allow more light pass through the TCO layer, lower dopant concentration results in lower carrier concentration, which reduces output current due to higher resistance. The converse is also true. Increasing doping improves carrier concentration, for better series resistance, but at the same time reduces transmittance, so that fewer photons are captured in the absorber layer.

Some embodiments described herein provide a TCO layer with a thickness gradient along a specific direction, from an end opposite the interconnect structure to at least the P1 scribe line of the interconnect structure. This design can reduce current density gradients and thus lead to reduced series resistance Rs of the solar cells.

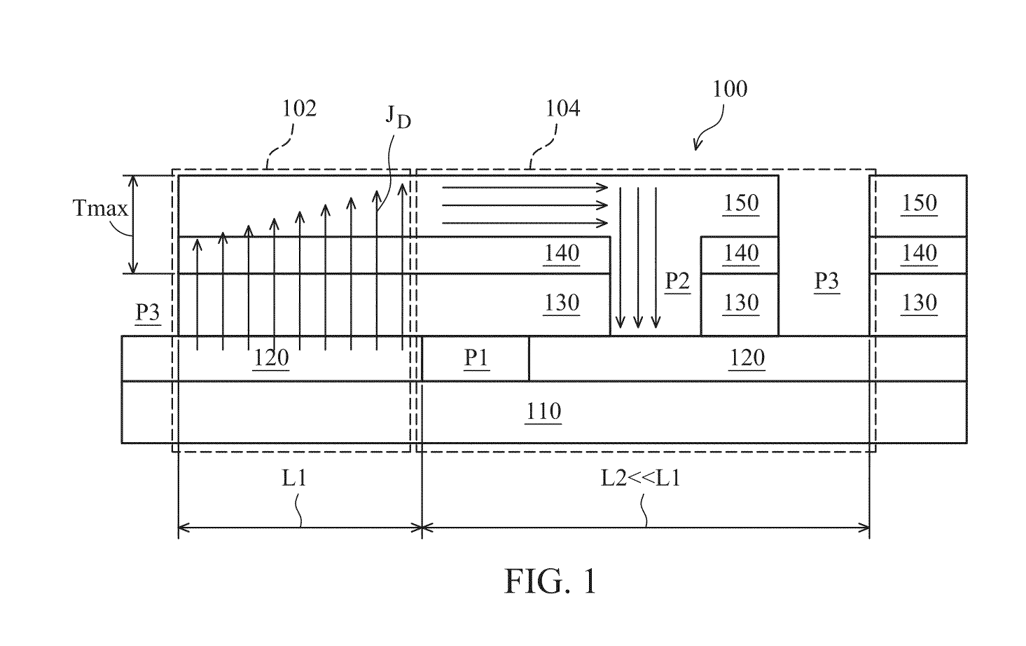

FIG. 1 is a cross sectional view of a solar cell 100 according to one embodiment. The solar cell 100 includes a solar cell substrate 110, a back contact layer 120, an absorber layer 130, a buffer layer 140 and a front contact layer 150.

Substrate 110 can include any suitable substrate material, such as glass. In some embodiments, substrate 110 includes a glass substrate, such as soda lime glass, or a flexible metal foil or polymer (e.g., a polyimide, polyethylene terephthalate (PET), polyethylene naphthalene (PEN)). Other embodiments include still other substrate materials.

Back contact layer 120 includes any suitable back contact material, such as metal. In some embodiments, back contact layer 120 can include molybdenum (Mo), platinum (Pt), gold (Au), silver (Ag), nickel (Ni), or copper (Cu). Other embodiments include still other back contact materials. In some embodiments, the back contact layer 120 is from about 50 nm to about 2 μm thick.

In some embodiments, absorber layer 130 includes any suitable absorber material, such as a p-type semiconductor. In some embodiments, the absorber layer 130 can include a chalcopyrite-based material comprising, for example, Cu(In,Ga)Se₂ (CIGS), cadmium telluride (CdTe), CuInSe₂ (CIS), CuGaSe₂ (CGS), Cu(In,Ga)Se₂ (CIGS), Cu(In,Ga)(Se,S)₂ (CIGSS), CdTe or amorphous silicon. Other embodiments include still other absorber materials. In some embodiments, the absorber layer 140 is from about 0.3 μm to about 8 μm thick.

Buffer layer 140 includes any suitable buffer material, such as n-type semiconductors. In some embodiments, buffer layer 140 can include cadmium sulphide (CdS), zinc sulphide (ZnS), zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer 140 is from about 1 nm to about 500 nm thick.

In some embodiments, front contact layer 150 includes an annealed transparent conductive oxide (TCO) layer of constant thickness of about 100 nm or greater. The terms “front contact” and “TCO layer” are used interchangeably herein; the former term referring to the function of the layer 150, and the latter term referring to its composition. In some embodiments, the charge carrier density of the TCO layer 150 can be from about 1×10¹⁷ cm⁻³ to about 1×10¹⁸ cm⁻³. The TCO material for the annealed TCO layer can include suitable front contact materials, such as metal oxides and metal oxide precursors. In some embodiments, the TCO material can include AZO, GZO, AGZO, BZO or the like) AZO: alumina doped ZnO; GZO: gallium doped ZnO; AGZO: alumina and gallium co-doped ZnO; BZO: boron doped ZnO. In other embodiments, the TCO material can be cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant.

In some embodiments, in the doped TCO layer 150, SnO₂ can be doped with antimony, (Sb), flourine (F), arsenic (As), niobium (Nb) or tantalum (Ta). In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In₂O₃ can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants.

The layers 120, 130, 140 and 150 are provided in the collection region 102. Solar cell 100 also includes an interconnect structure 104 that includes three scribe lines, referred to as P1, P2, and P3. The P1 scribe line extends through the back contact layer 130 and is filled with the absorber layer material. The P2 scribe line extends through the buffer layer 150 and the absorber layer 140, and contacts the back contact 130 of the next adjacent solar cell. The P2 scribe line is filled with the front contact layer material forming the series connection between adjacent cells. The P3 scribe line extends through the front contact layer 160, buffer layer 150 and absorber layer 140. The P3 scribe line of the adjacent solar cell is immediately to the left of the solar cell collection region 102. In FIGS. 1-5, the width of the interconnect structure 104 is exaggerated relative to the width of the collection region 102 for clarity, but the collection region 102 is actually much larger than the interconnect structure. That is, the length L1 is much greater than the length L2. The collection region 102 and interconnect structure 104 alternate across the width of the solar panel.

When the solar cell 100 is exposed to light, charge carriers within the absorber layer 130 are released, and flow upward through the absorber layer 130 and buffer layer 140 to the front contact layer 150. The charge carriers in the front contact layer 150 flow to the right towards the interconnect structure. The current at any given region in the front contact layer 150 is the sum of the current generated in the absorber directly below that region plus the current collected upstream (i.e., to the left of that region). Thus, the current density increases continuously from the left side of the front contact layer 150 to the P1 scribe line on the right side. This increasing current density is indicated by the arrows J_{D} in the collection region 102 of the solar cell 100. The photon absorption effectively ends at the P1 scribe line, so that the current density stops increasing, as indicated by the horizontal arrows in FIG. 1. The current then flows downward through the P2 scribe line into the back contact layer 120 of the next adjacent solar cell 100.

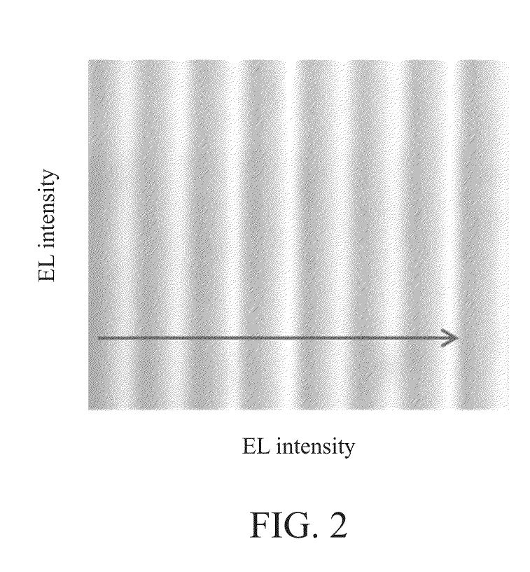

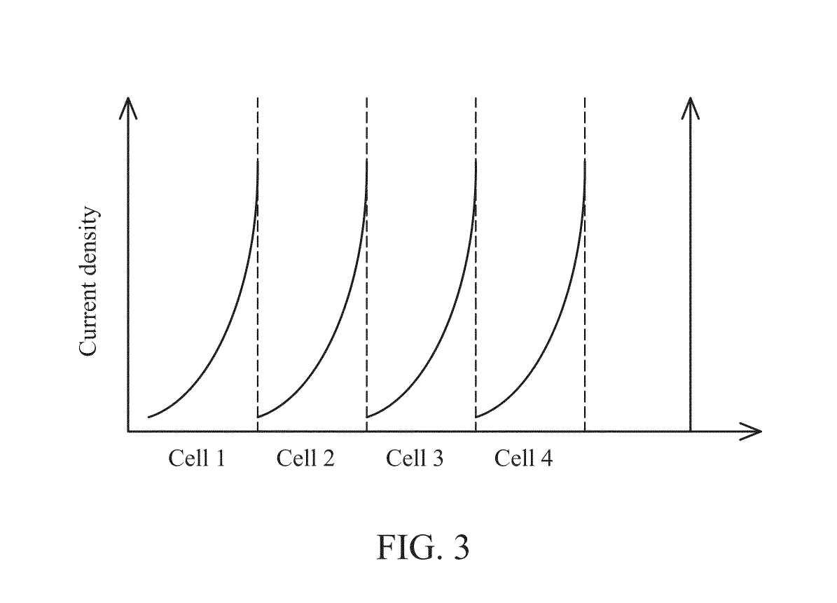

FIG. 2 is an image showing the electroluminescence (EL) intensity of a solar panel. Here, EL is an optical phenomenon in which the front electrode layer 150 emits light in response to the passage of an electric current. The periodic bands in FIG. 3 correspond to the locations of solar cells within a solar panel. Thus, the EL intensity gradient pattern indicates that the current density increases within each solar cell.

FIG. 3 is a schematic diagram showing how the current density increases in each solar cell within a solar panel, as indicated by the EL intensity image. In each series connected solar cell of the solar panel, the current density increases beginning immediately to the right of the P3 scribe line of the adjacent solar cell to the left, and keeps increasing until the P1 scribe line.

The current density gradient can increase series resistance, induce localized high temperatures, and create hot spots.

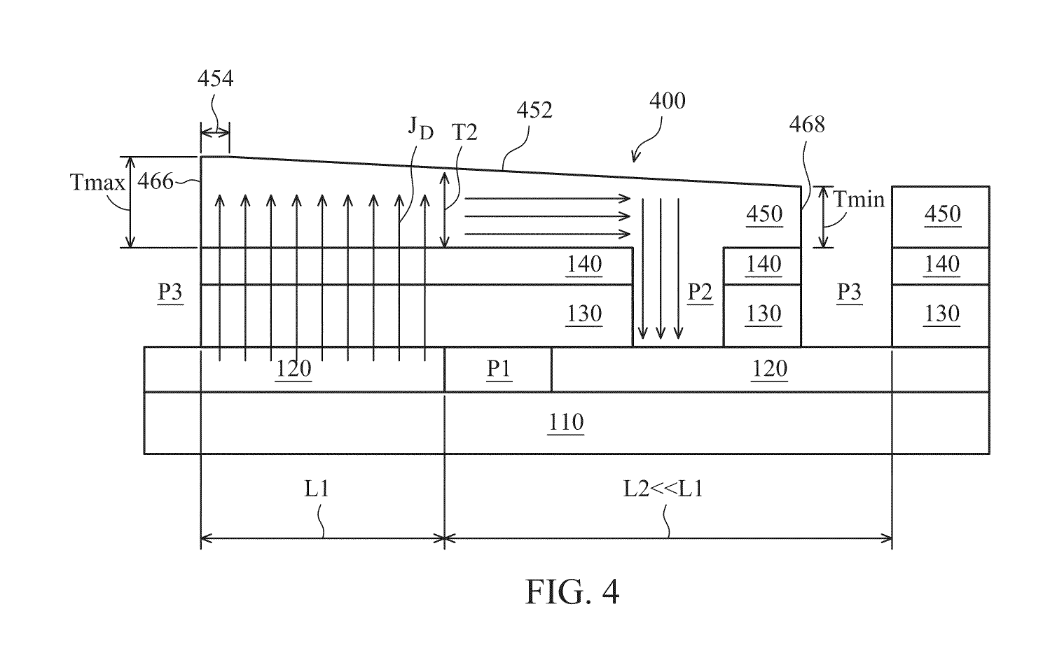

FIG. 4 shows another solar cell 400 according to some embodiments. The solar cell 400 has a substrate 110, back contact layer 120, absorber layer 130, buffer layer 140, and P1, P2 and P3 scribe lines, which can be the same as the corresponding like-numbered items in FIG. 1 and described above. For brevity, the descriptions of these items are not repeated.

In some embodiments, the front contact layer 450 has a thickness gradient. In some embodiments, the front contact layer 450 has a first end 466 and a second end 468 opposite the first end 466, wherein the P1 scribe line is closer to the second end 468 than to the first end 466, and the front contact layer 450 has a thickness T2 above the P1 scribe line. The thickness Tmax of the TCO at the first end 466 is greater than the thickness T2 of the TCO at the P1 scribe line. In some embodiments, the thickness T2 of the TCO layer above the P1 scribe line is also greater than the thickness Tmin of the front contact layer at the second end. In some embodiments, the thickness Tmin can be about 100 nm or more.

In some embodiments, the thickness Tmax of the front contact layer 450 at the first end 466 is about twice the thickness Tmin of the front contact layer at the second end 468.

In some embodiments, the thickness Tmax of the front contact layer 450 at the first end 466 is about 200 nm or more, and the thickness Tmin of the front contact layer 450 is about 100 nm or more at the second end 468. In some embodiments, the thickness Tmin of the TCO at the second end 466 is selected to be approximately as thick as the front contact layer 150 of a solar cell 100 (FIG. 1) having a front contact layer of uniform thickness.

In some embodiments, as shown in FIG. 4, the thickness of the front contact layer 450 decreases continuously from a value of Tmax at approximately the first end 466 (i.e., at or near the first end 466) at least to a value of T2 at the P1 scribe line. In some embodiments, the front contact 450 has a small region of uniform thickness Tmax extending a short length 454 from the first end 466. In some embodiments, the length 454 can be in a range from 0 nm to 5 mm.

In some embodiments, as shown in FIG. 4, the thickness of the front contact layer 450 decreases linearly from a value of Tmax at approximately the first end 466 (near the P3 scribe line of the adjacent solar cell) to a value of Tmin at the second end 468 (at the P3 scribe line of the solar cell 400. The top surface 452 of the front contact layer 450 is a line in the cross sectional view.

In other embodiments (not shown), the thickness of the front contact layer 450 decreases linearly from a value of Tmax at the first end 466 to a value of Tmin at the P1 scribe line, and the front contact layer 450 has a uniform thickness of Tmin from the P1 scribe line to the second end 468. Because the photon collection occurs in the collection region of the solar cell 400, the current density does not continue to increase in the interconnect structure, and there is no need to reduce the TCO thickness further between the P1 scribe line and the P3 scribe line.

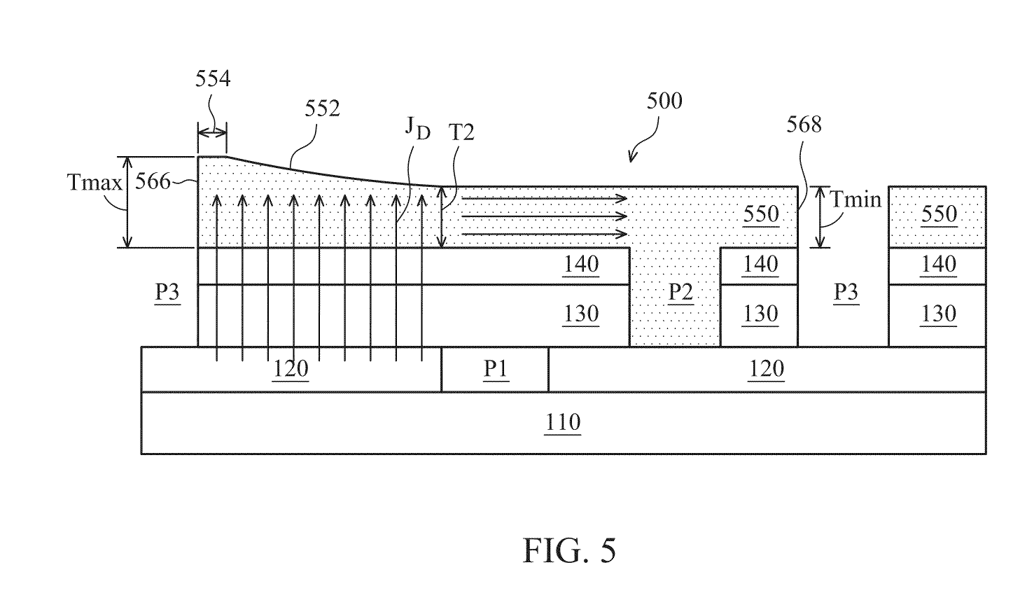

In other embodiments (as shown in FIG. 5), the top surface 552 can have a curved contour. FIG. 5 shows a top surface 552 of the front contact layer having a curvature between the first end and the second end in the cross sectional view. In some embodiments, the top surface 452 has a contour defined by a parabola, a hyperbola, an exponential or logarithmic curve or other suitable curvature to achieve a substantially uniform current density J_{D} from the first end 566 of the solar cell 500, at least to the P1 scribe line of the solar cell 500. Thus, the selection of a linear profile or a curved profile can be based on the profile which provides a more uniform current density J_{D}, which can be verified, for example, by comparing EL intensities.

In some embodiments, the thickness values Tmax and Tmin can be the same in the embodiments shown by solar cells 400 and 500 in FIGS. 4 and 5, respectively. In some embodiments, Tmax≧200 nm and Tmin≧100 nm. In some embodiments, Tmax˜2×Tmin.

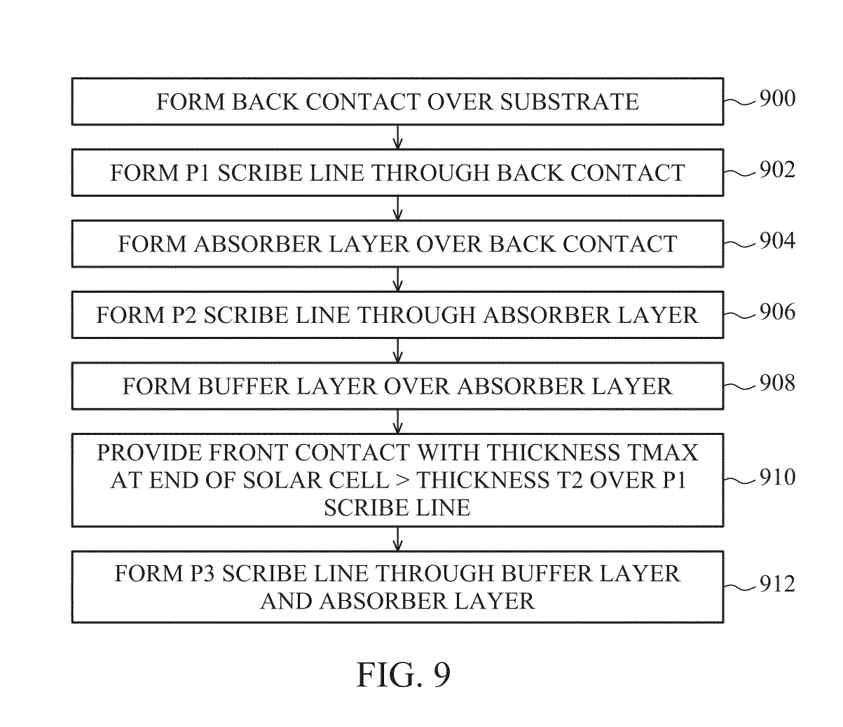

FIG. 9 is a flow chart of a method for making the solar cells of FIGS. 4 and 5.

At step 900, a back contact layer 120 is formed over a solar cell substrate. The back contact can deposited by PVD, for example sputtering, of a metal such as Mo, Cu or Ni over the substrate, or by CVD or ALD or other suitable techniques.

At step 902, the P1 scribe line is formed through the back contact layer 120. For example, the scribe line can be formed by mechanical scribing, or by a laser or other suitable scribing process. Each solar cell has a respective P1 scribe line.

At step 904, an absorber layer 130 is formed over the back contact layer 120. The absorber layer 130 can be deposited by PVD (e.g., sputtering), CVD, ALD, electro deposition or other suitable techniques. For example, a CIGS absorber layer can be formed by sputtering a metal film comprising copper, indium and gallium then applying a selenization process to the metal film.

At step 906, the P2 scribe line is formed through the absorber layer 130. For example, the scribe line can be formed by mechanical scribing, or by a laser or other suitable scribing process.

At step 908, the buffer layer 140 is formed over the absorber layer 130. The buffer layer 140 can be deposited by chemical deposition (e.g., chemical bath deposition), PVD, ALD, or other suitable techniques.

At step 910, a front contact layer 450 or 550 is formed over the buffer layer 140, which is over the absorber layer 130. The front contact layer 450, 550 has a first end 466, 566 and a second end 468, 568, wherein the P1 scribe line is closer to the second end 468 than to the first end 466, and a thickness Tmax of the front contact layer 450, 550 at the first end is greater than the thickness T2 of the front contact layer above the P1 scribe line. In some embodiments, the step of forming the front contact layer comprises selectively depositing more front contact layer material near the first end than is deposited at the second end.

At step 912, the P3 scribe line is formed through the buffer layer 140 and the absorber layer 130.

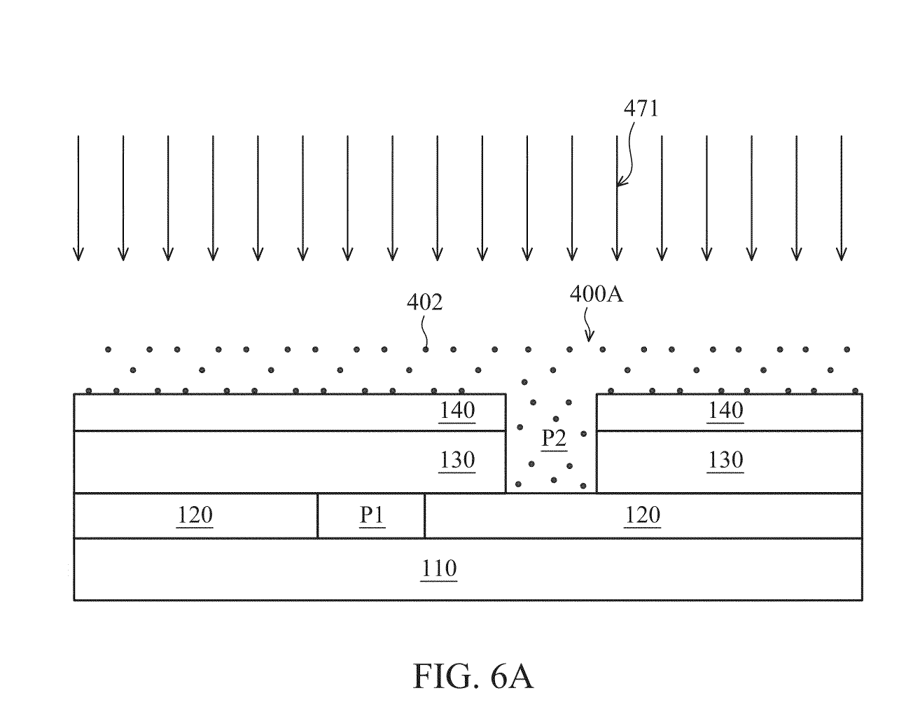

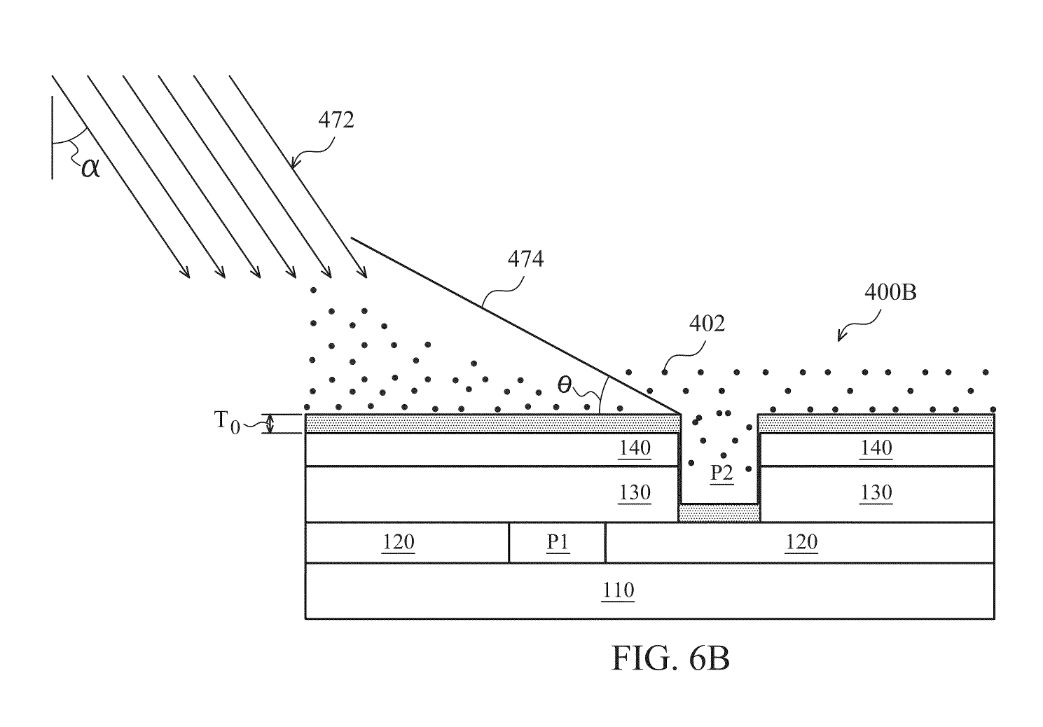

FIGS. 6A and 6B show an embodiment of step 910, for forming the front contact layer with a thickness gradient, including selectively depositing more of a front contact layer material near the first end 466 than is deposited at the second end 468.

In some embodiments, the step 910 of forming the front contact layer 450 includes a first step of depositing a substantially uniform layer of the front contact layer material, and a second step including varying an angle between a stream of the front contact layer material and a top surface of the buffer layer while depositing the front contact layer material.

The first step of depositing a substantially uniform layer of material 402 is shown in FIG. 6A. The material can be deposited to a thickness T₀ (shown in FIG. 6B) by sputtering or metal organic chemical vapor deposition (MOCVD). In some embodiments, the thickness T₀ is in a range from 1 nm to 3 μm. In the first step (FIG. 6A), the stream 471 of vapor or ions is directed perpendicular to the top surface of the buffer layer 140.

In the second step, as shown in FIG. 6B, the angle θ is varied by changing an angle of a shutter mechanism 474 of a vapor deposition apparatus (e.g., a sputtering or MOCVD apparatus). The shutter mechanism 474 alters the flow path of the material. In various embodiments, the angle θ can be from 1 degree to 89 degrees. In some embodiments, the angle α of the material stream 472 is adjusted, so that the stream of front contact material is directed at an oblique angle, which is not perpendicular to the top surface of the buffer layer 140. For example, the stream angle can be adjusted by a method and mask assembly as described in U.S. Patent Application Publication No. 2004/0086639, which is incorporated by reference herein in its entirety. Other methods for adjusting the angle of the material stream 472 can be used. In some embodiments, the angle θ of the shutter 474 is varied, and the angle α of stream 472 is also adjusted.

The apparatus includes a controller (e.g., microcontroller, embedded processor, microcomputer, mobile device, or the like) (not shown), programmed to selectively actuate the shutter 474 for shaping the flow of material that reaches the substrate.

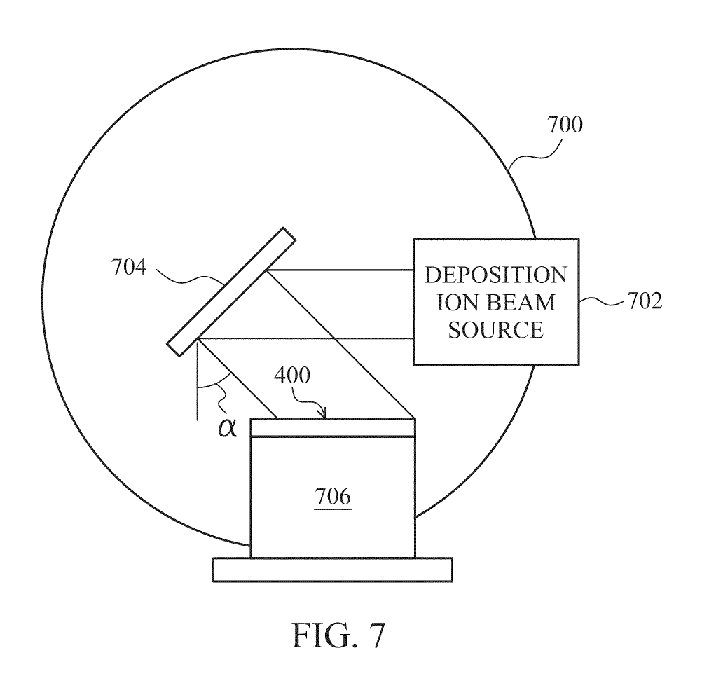

FIG. 7 shows an alternative apparatus and method for varying the stream angle α of the front contact layer material. The apparatus includes a chamber 700 having a solar panel substrate 400 contained therein on a substrate support 706. A sputter target 704 is located at an oblique angle relative to the substrate. The rotation angle of the sputter target 704 is adjustable. A re-positionable deposition ion beam source 702 is located in the chamber. By varying the position of the ion beam source 702, the angle of incidence between the ions and the target is varied, so that the ions leaving the target are ejected at an angle α that is not perpendicular to the substrate 400.

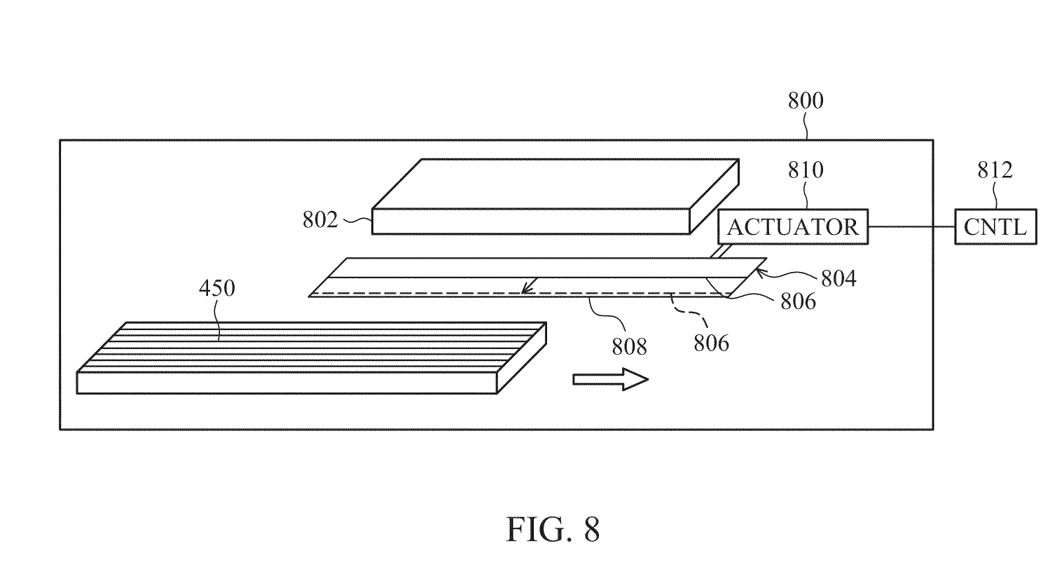

FIG. 8 shows another embodiment of an apparatus for varying the thickness of the front contact layer 450. The apparatus includes a chamber 800 having a sputter target and one or more adjustable aperture plate 804 between the substrate 110 and the target 802. In this apparatus 800, the material stream is perpendicular to the substrate, and the thickness is varied by opening or closing the aperture of the sputter tool. The aperture plate 804 has an edge 806 which is movable to define an aperture 808. The plate(s) 804 can be moved from a retracted position, in which the aperture 808 is larger, and an extended position (shown in phantom) in which the aperture 808 is smaller. In some embodiments, the plate(s) 804 can be moved continuously by an actuator 810 under control of a controller 812, which can be a programmable logic controller, microcomputer, embedded microprocessor or microcontroller, or other processing device. By controlling the position of the plate(s) 604, a continuous thickness profile can be achieved. Using the apparatus of FIG. 8, the selective depositing comprises varying an aperture size 808 of a transparent conductive oxide material source while depositing the front contact layer material.

Although FIG. 8 shows a single aperture plate 804, the apparatus can include plural aperture plates (one plate per solar cell) which open or close in parallel, to deposit a TCO layer 450 of varying thickness on plural solar cells 400 on the same substrate 110. Other elements of the sputtering apparatus, including the ion beam source and inert gas supply are omitted from FIG. 8 for clarity.

The methods described herein can be applied to thin film solar cells of a variety of types, including but not limited to: amorphous silicon thing film, CIGS, and CdTe types, with p-n junction, p-i-n structure, metal-insulator-semiconductor (MIS) structure, multi-junction structure or the like.

This disclosure provides a cost efficient, high yield manufacturing process for improving the series resistance for higher efficiency of thin film solar cells. High throughput can be obtained with this method. The process can be integrated into existing solar cell production lines. The resulting solar cells with the TCO thickness gradient have more uniform current density, so the risk of hot spots is reduced.

In some embodiments, a solar cell comprises a back contact layer over a substrate. The back contact layer has a scribe line extending therethrough. An absorber layer is over the back contact layer. A front contact layer is over the absorber layer. The front contact layer has a first end and a second end opposite the first end. The scribe line is closer to the second end than to the first end. The front contact layer has a thickness above the first end that is greater than the thickness of the front contact layer at the scribe line.

In some embodiments, a solar cell comprises a back contact layer over a substrate. The back contact layer has a P1 scribe line extending therethrough. An absorber layer is provided over the back contact layer. A front contact layer is provided over the absorber layer. The solar cell is adjacent to a first P3 scribe line at a first end of the solar cell. The solar cell has a second P3 scribe line at a second end opposite the first end. Each P3 scribe line extends through the front contact layer and the absorber layer. The P1 scribe line is closer to the second end than to the first end. The front contact layer has a thickness above the first end that is greater than the thickness of the front contact layer at the P1 scribe line

In some embodiments, a method, comprises: forming a back contact layer over a solar cell substrate; forming a scribe line through the back contact layer; forming an absorber layer over the back contact layer; and forming a front contact layer over the absorber layer. The front contact layer has a first end and a second end. The scribe line is closer to the second end than to the first end. A thickness of the front contact layer at the first end is greater than the thickness of the front contact layer above the scribe line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell comprising:
a back contact layer over a substrate, the back contact layer having a scribe line extending therethrough;
an absorber layer over the back contact layer; and
a front contact layer over the absorber layer, the front contact layer having a first end and a second end opposite the first end, wherein the scribe line is closer to the second end than to the first end, and the front contact layer has a thickness above the first end that is greater than the thickness of the front contact layer at the scribe line.

2. The solar cell of claim 1, wherein the thickness of the front contact layer decreases continuously from approximately the first end to the scribe line.

3. The solar cell of claim 1, wherein the thickness of the front contact layer decreases continuously from approximately the first end to the second end.

4. The solar cell of claim 1, wherein the thickness of the front contact layer decreases linearly between the first end and the second end.

5. The solar cell of claim 1, wherein a top surface of the front contact layer has a curvature between the first end and the second end.

6. The solar cell of claim 1, wherein the thickness of the front contact layer at the first end is about twice the thickness of the front contact layer at the second end.

7. The solar cell of claim 1, wherein the thickness of the front contact layer at the first end is about 200 nm or more, and the thickness of the front contact layer is about 100 nm or more at the second end.

8. The solar cell of claim 1, wherein the scribe line is a P1 scribe line, and the solar cell is adjacent to a first P3 scribe line at the first end of the solar cell, the first P3 scribe line extending through the front contact layer and the absorber layer, and wherein the thickness of the front contact layer decreases linearly from the first P3 scribe line to the P1 scribe line.

9. The solar cell of claim 8, wherein the solar cell has a second P3 scribe line at the second end, and the thickness of the front contact layer decreases linearly from approximately the first P3 scribe line to the second P3 scribe line.

10. A solar cell comprising:
a back contact layer over a substrate, the back contact layer having a P1 scribe line extending therethrough;
an absorber layer over the back contact layer; and
a front contact layer over the absorber layer, the solar cell being adjacent to a first P3 scribe line at a first end of the solar cell, the solar cell having a second P3 scribe line at a second end opposite the first end, each P3 scribe line extending through the front contact layer and the absorber layer, wherein the P1 scribe line is closer to the second end than to the first end, and the front contact layer has a thickness above the first end that is greater than the thickness of the front contact layer at the P1 scribe line.

11. The solar cell of claim 10, wherein the thickness of the front contact layer decreases continuously at least from the first end to the P1 scribe line.

12. The solar cell of claim 10, wherein the thickness of the front contact layer decreases linearly from the approximately first end to the second end.

13. The solar cell of claim 10, wherein a top surface of the front contact layer has a curvature between the first end and the second end.

14. A method, comprising:
forming a back contact layer over a solar cell substrate;
forming a scribe line through the back contact layer;
forming an absorber layer over the back contact layer;
forming a front contact layer over the absorber layer, the front contact layer having a first end and a second end, wherein the scribe line is closer to the second end than to the first end, and a thickness of the front contact layer at the first end is greater than the thickness of the front contact layer above the scribe line.

15. The method of claim 14, wherein the step of forming the front contact layer comprises:
selectively depositing more of a front contact layer material near the first end than is deposited at the second end.

16. The method of claim 15, wherein the depositing step includes varying an angle between a stream of the front contact layer material and a top surface of the buffer layer while depositing the front contact layer material.

17. The method of claim 16, wherein the angle is varied by changing an angle of a shutter mechanism of a vapor deposition apparatus.

18. The method of claim 17, wherein the depositing includes performing metal organic chemical vapor deposition.

19. The method of claim 14, wherein the selectively depositing comprises varying an aperture size of a transparent conductive oxide material source while depositing the front contact layer material.

20. The method of claim 19, wherein the depositing includes sputtering.
